(19) United States
(12) Patent Application Publication
(10) Pub. No.: US 2003/0124838 A1
(43) Pub. Date: Jul. 3, 2003

(54) Method of forming cooper damascene interconnect

(76) Inventor: Chao-Yuan Huang, Hsinchu (TW)

Correspondence Address: MERCHANT & GOULD PC, P.O. BOX 2903, MINNEAPOLIS, MN, 55402-0903, US

(21) Appl. No.: 10/165,793

(22) Filed: Jun. 7, 2002

(30) Foreign Application Priority Data
Dec. 31, 2001 (TW) 90133413

(51) Int. Cl. H01L 21/4763; H01L 21/44

(52) U.S. Cl. 438/633; 438/634; 438/687

(57) ABSTRACT

A method of forming a cooper damascene interconnect. First, a metal and a dielectric layer are formed on a substrate in sequence. Next, a damascene opening is formed in the dielectric layer. A metal barrier/Cu seed layer is then formed on the dielectric layer conformally. CMP is performed to remove parts of the metal barrier/Cu seed layer covering on the surface of the dielectric layer. A chemical electroplating is performed to form a Cu layer filling the damascene opening on the metal barrier/Cu seed layer. Finally, CMP is performed.

### BACKGROUND OF THE INVENTION

1. Field of the Invention

The present invention relates in general to semiconductor manufacturing, and particularly to fabricating a damascene interconnect.

2. Description of the Related Art

As methods of fabricating semiconductor integrated circuits (IC) continually improve, the number of devices that may be introduced into a single semiconductor chip has increased, while the size of each device has decreased. Millions of devices may now be fabricated on a single chip. After the formation of the devices, metal lines for interconnection are defined using a metallization process. As the integration of integrated circuits increases, manufacturing with high yield and highly reliable metal interconnect lines is hard to achieve. A method of fabricating a metal-damascene structure is to etch trenches for metal interconnect lines and then fill the trenches with metal material. In addition, chemical mechanical polishing (“CMP” hereinafter) is used to polish the metal material. The method, so-called damascene process, offers a better way to fabricate a submicron VLSI interconnection with high performance and high reliability.

An exemplary prior-art damascene interconnect fabrication process is shown in FIG. 1A through FIG. 1E.

In FIG. 1A, a metal layer 104 is formed by known technique on a substrate 102. An inter-metal dielectric layer (IMD) 106 is preferably formed by chemical vapor deposition (CVD) on the metal layer 104. The substrate 102 comprises prior-art devices (not shown), such as transistor.

In FIG. 1B, a photolithographic process and an etch are performed, thereby a damascene opening I is formed in the inter-metal dielectric layer 106.

In FIG. 1C, a barrier metal/Cu seed layer 108 is formed conformally to cover the surface of the patterned inter-metal dielectric layer 106a and the side wall and the bottom of the damascene opening I. The barrier layer 108 can prevent oxidation and diffusion of the Cu following deposited, wherein the material of the barrier layer 108 comprises Ta, Ti, W, TaN, TiN, or WN.

In FIG. 1D, a well known electroplating process is performed to form a Cu layer 110 filling the damascene opening I on the barrier metal/Cu seed layer 108.

Finally, the Cu layer 110 and the barrier metal/Cu seed layer 108 are subjected to CMP until the surface of the patterned inter-metal dielectric layer 106a is exposed.

However, CMP is difficult to control and uses a lot of time due to strong adhesion between the Cu layer 110 and the inter-metal dielectric layer 106. Therefore, efficiency is decreased, and the dishing structure of the Cu layer due to the length of CMP will appear if the interconnect is wide.

### SUMMARY OF THE INVENTION

The object of the present invention is to provide a method of forming a Cu layer in a damascene interconnect with shortened CMP time to avoid the dishing structure of the Cu layer.

The method comprises the following steps. First, a metal and a dielectric layer are formed sequentially on a substrate. Next, a damascence opening is formed in the dielectric layer. A metal barrier/Cu seed layer is then formed on the dielectric layer conformally. CMP is performed to remove a portion of the metal barrier/Cu seed layer covering on the surface of the dielectric layer. Chemical electroplating is performed to form a Cu layer filling the damascence opening on the metal barrier/Cu seed layer. Finally, CMP is performed.

In accordance with the concept of the present invention, the damascene opening further comprises a via. Additionally, the dielectric layer comprises an oxide formed by plasma enhanced chemical vapor deposition (PECVD), and the material of the barrier metal comprises TiN, Ta, or TaN.

### BRIEF DESCRIPTION OF THE DRAWINGS

The above and other objects, features, and advantages of the present invention will become apparent from the following detailed description of preferred embodiments of the invention explained with reference to the accompanying drawings, in which:

FIGs. 1A-1E are schematic cross-sections illustrating steps for fabricating a damascene interconnect according to the prior art.

FIGS. 2A-2F are schematic cross-sections illustrating steps for fabricating a damascene interconnect according to the preferred embodiment of the invention.

### DETAILED DESCRIPTION OF THE INVENTION

There will now be described an embodiment of this invention with reference to the accompanying drawings.

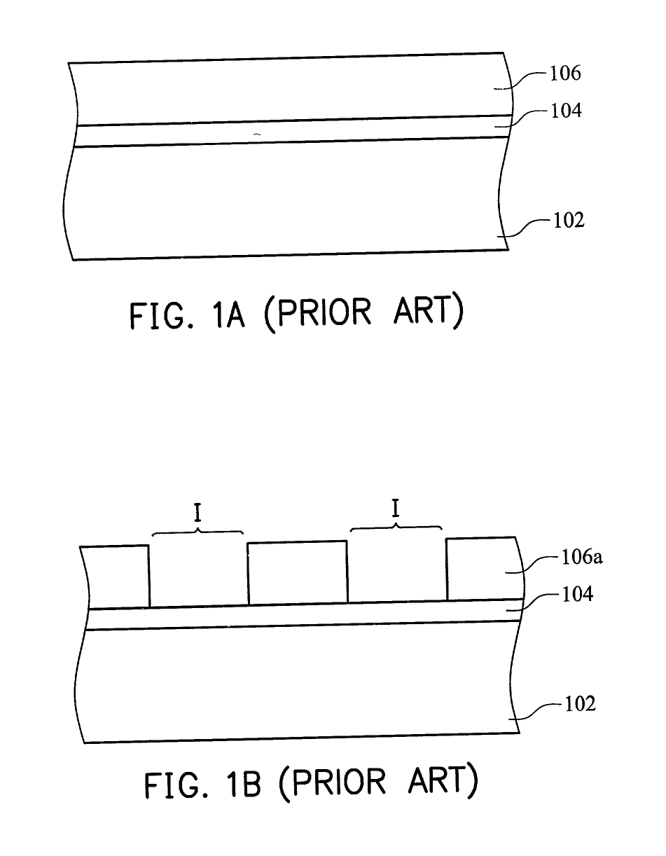

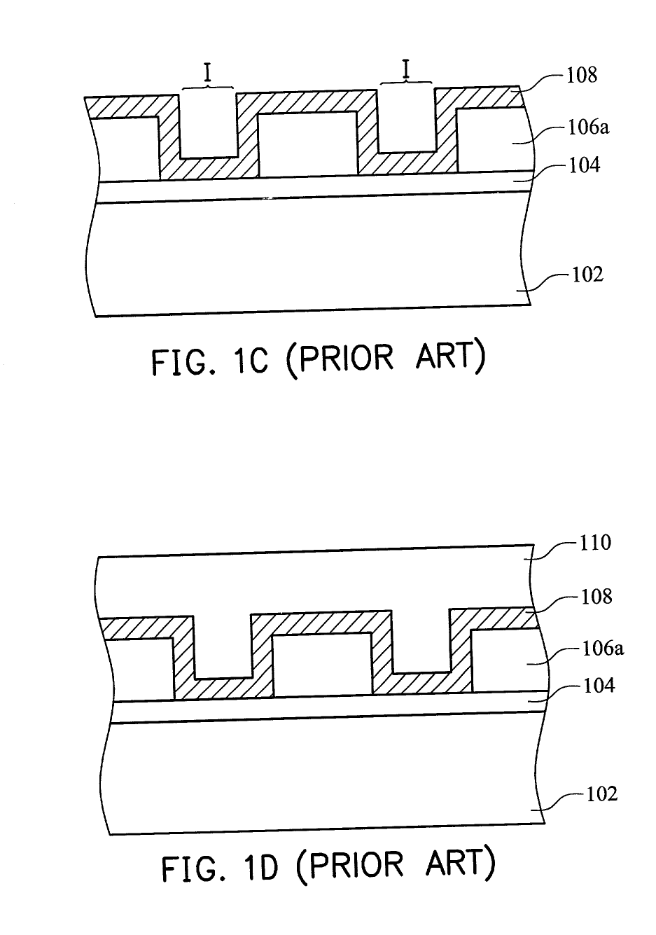

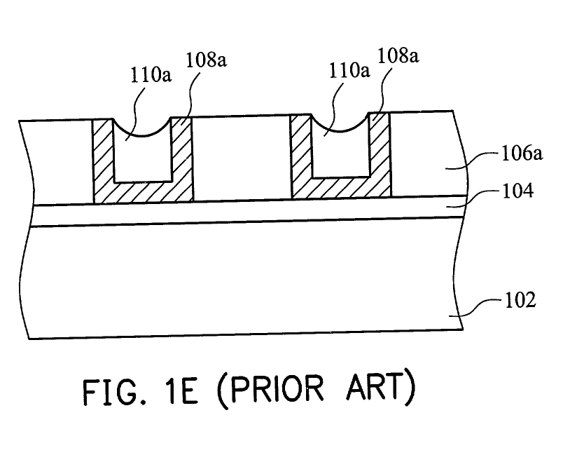

In FIG. 1A, a metal layer 240 is formed by known metallization technique on a substrate 220. The substrate 220 comprises any prior-art devices (not shown), such as transistors. An inter-metal dielectric layer (IMD) 260 is preferably formed by chemical vapor deposition (CVD) on the metal layer 240. The material of the inter-metal dielectric layer 206 comprises SiO₂, phoshosilicate glass(PSG), boro-phospho silicate glass (BPSG), fluosilicate glass (FSG).

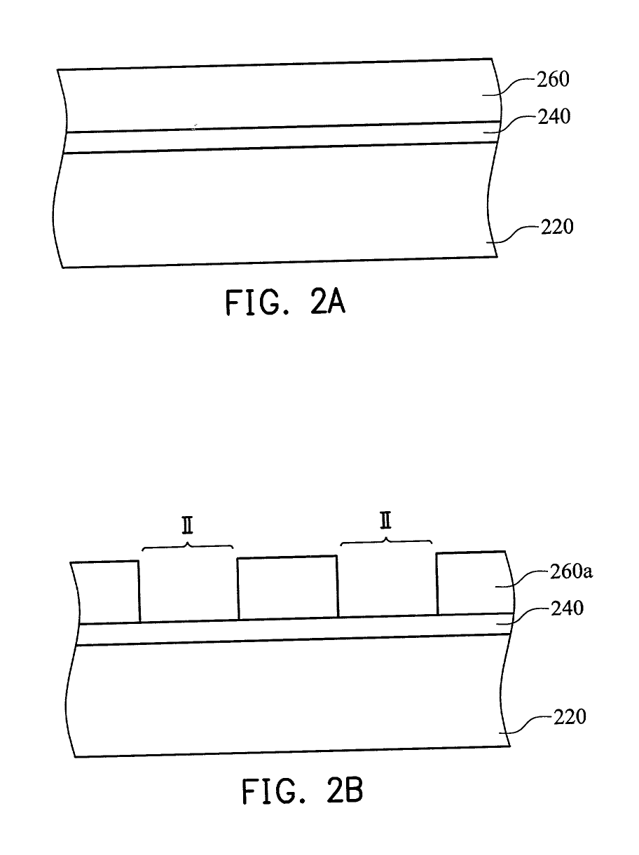

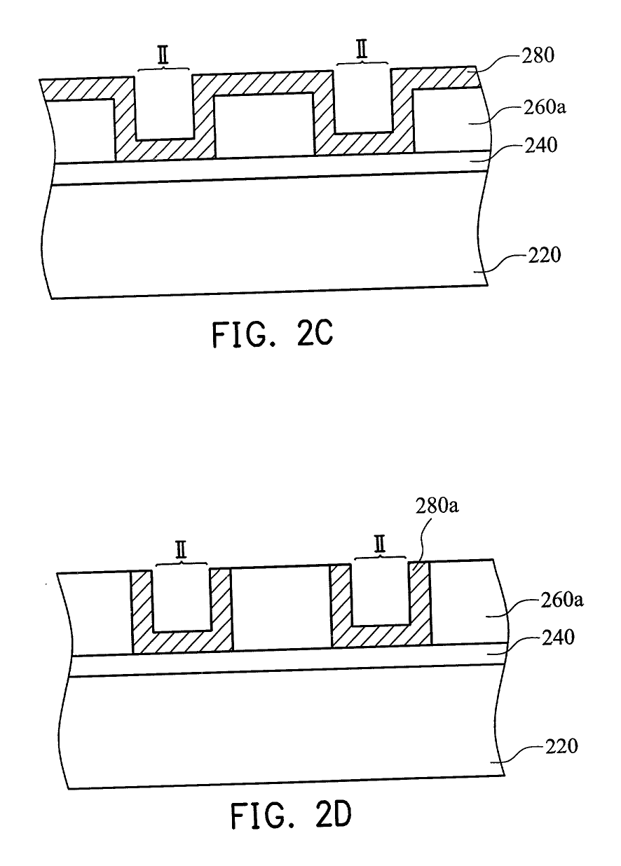

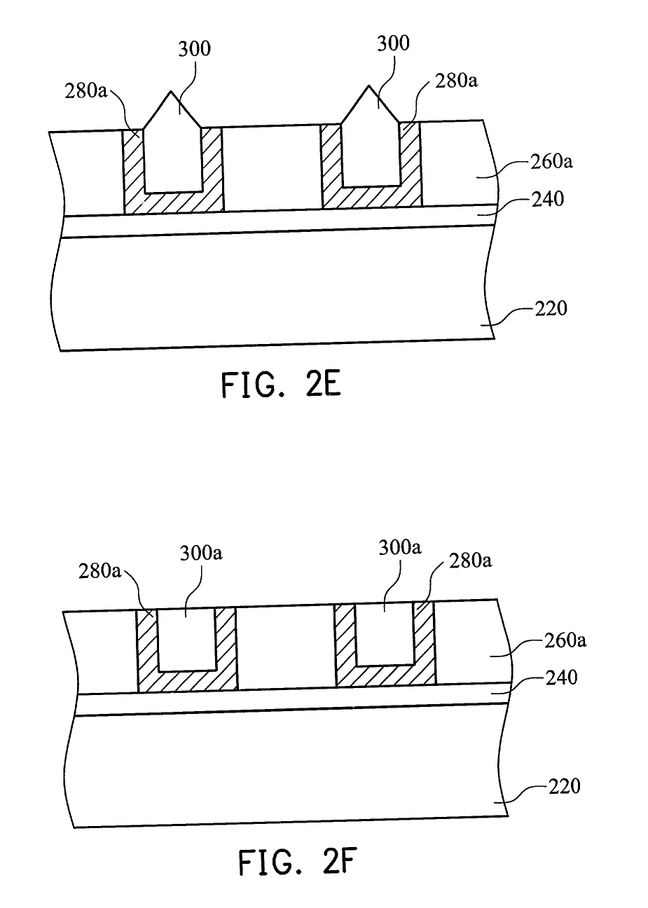

In FIG. 2B, a photolithography and an etch, such as a reactive ion etching(RIE), are then performed, thereby forming a damascene opening II in the inter-metal dielectric layer 260.

In FIG. 2C, a barrier metal/Cu seed layer 280 is formed conformally to cover the surface of the patterned inter-metal dielectric layer 260a, the side wall, and bottom of the damascene opening II. The barrier layer 280 prevents oxidation and diffusion of the Cu following deposit, wherein the material of the barrier layer 108 comprises Ta, Ti, W, TaN, TiN, or WN.

I In FIG. 2D, a CMP is preferably performed to remove a portion of the barrier metal/Cu seed layer 280a covering on the surface of the dielectric layer 260a. The portion of the barrier metal/Cu seed layer 280a on the bottom and side wall of the damascene opening II remains to ensure that the following copper is formed in the damascene opening II.

In FIG. 2E, known electroplating fis performed to form a Cu layer 300 filling the damascene opening II on the barrier metal/Cu seed layer 280a.

In FIG. 2F, the Cu layer 300 and the barrier metal/Cu seed layer 108 are subjected to a planarization, such as CMP, until the surface of the patterned inter-metal dielectric layer 260a is exposed.

According to the concept of the present invention, the damascene opening II further comprises a via. A copper dual damascene interconnect can also be formed according to the present invention.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method of forming a cooper damascene interconnect, comprising:
providing a substrate;
forming a metal and a dielectric layer sequentially;
forming a damascence opening in the dielectric layer;
forming a metal barrier/Cu seed layer on the dielectric layer conformally;
removing a portion of the metal barrier/Cu seed layer layer covering on the surface of the dielectric layer;
performing a chemical electroplating to form a Cu layer filling the damascence opening on the metal barrier/Cu seed layer; and
performing a planarization process.

2. The method as claimed in claim 1, wherein the damascene opening further comprises a via.

3. The method as claimed in claim 1, wherein the dielectric layer comprises an oxide formed by plasma enhanced chemical vapor deposition (PECVD).

4. The method as claimed in claim 1, wherein the material of the barrier metal comprises TiN, Ta, or TaN.

5. The method as claimed in claim 1, wherein the planarization comprises chemical mechanical polishing (CMP).

6. A method of forming a cooper damascene interconnect, comprising:
providing a substrate;
forming a metal and a dielectric layer sequentially;
forming a damascence opening in the dielectric layer;
forming a metal barrier/Cu seed layer on the dielectric layer conformally;
performing a chemical mechanical polishing (CMP) to remove parts of the metal barrier/Cu seed layer covering on the surface of the dielectric layer;
performing a chemical electroplating to form a Cu layer filling the damascence opening on the metal barrier/Cu seed layer; and
performing a chemical mechanical polishing (CMP).

7. The method as claimed in claim 6, wherein the damascene opening further comprises a via.

9. The method as claimed in claim 6, wherein the dielectric layer comprises an oxide formed by plasma enhanced chemical vapor deposition (PECVD).

10. The method as claimed in claim 6, wherein the material of the barrier metal comprises TiN, Ta, or TaN.

11. The method as claimed in claim 6, wherein the planarization comprises chemical mechanical polishing (CMP).
